(19) United States
(12) Patent Application Publication
(10) Pub. No.: US 2022/0284453 A1
(43) Pub. Date: Sep. 8, 2022

(54) METHOD FOR CREATING A STORE ON AN ONLINE RETAIL PLATFORM

(71) Applicant: JUDA UNIVERSE SDN. BHD, Kajang (MY)

(72) Inventors: Fu Seng LOO, Kajang (MY); Fook Wah CHEN, Kajang (MY)

(73) Assignee: JUDA UNIVERSE SDN. BHD, Kajang (MY)

(21) Appl. No.: 17/625,086

(22) PCT Filed: Nov. 29, 2020
(86) PCT No.: PCT/MY2020/050176

§ 371 Date: Jan. 5, 2022

(30) Foreign Application Priority Data
Nov. 13, 2020 (MY) PCT/MY2020/050149

(51) Int. Cl. G06Q 30/02

(52) U.S. Cl. CPC G06Q 30/0201

(57) ABSTRACT

A method for creating a virtual store on an online retail platform that automatically identifies the type of file being uploaded by the merchant from any of media files such as images and video, 3D-scan files, and computer-aided-design (CAD) files. The method then registers certain parameters of the uploaded store, and finds a set of stores located in a multitude of stored files, that are close enough in those parameters to the uploaded store. The method then generates a dataset of information from the set of stores that may be relevant to the uploaded store, and displays this to the merchant. This allows the merchant to select information from this dataset that they wish to apply to the uploaded store, thus saving time and effort when creating a virtual store.

### FIELD OF INVENTION

The present invention relates generally to a method for managing an online retail platform, and specifically to one that allows a merchant to create a virtual store on an online retail platform.

### BACKGROUND OF INVENTION

There are many online retail platforms that allow the merchants themselves to create virtual stores on those platforms. Most of these are manual methods, and depending on the type of online store, may require the merchant to perform time consuming tasks, have substantial computer skills, or purchase proprietary systems including software and hardware. In some of these methods, the merchant is required to design the store layout including the visitor walkways and the placement of shelves and products. If the merchant chooses to create a store based on an existing physical store, they may be required to upload multiple files including images, videos, or 3-D scans, in a specific manner and sequence required by the platform.

What is needed in the art is a virtual store creation method that allows a merchant to create a virtual store on an online retail platform that reduces the effort and expertise needed by the merchant.

### SUMMARY OF INVENTION

The present invention seeks to overcome the aforementioned disadvantages by providing a method for creating a virtual store on an online retail platform that automatically identifies the type of file being uploaded by the merchant from any of media files such as images and video, 3D-scan files, and computer-aided-design (CAD) files. The method then registers certain parameters of the uploaded store, and finds a set of stores located in a multitude of stored files, that are close enough in those parameters to the uploaded store. The method then generates a dataset of information from the set of stores that may be relevant to the uploaded store, and displays this to the merchant. This allows the merchant to select information from this dataset that they wish to apply to the uploaded store, thus saving time and effort when creating a virtual store.

The present invention thus relates to a computer-based method for a user to create a virtual store on an online retail platform, comprising the steps of:
a. the user uploading at least one file to a web server;
b. the web server detecting the type of said uploaded file from any of the following types: text information file, media such as images and video, 3D-scan, and computer-aided-design (CAD) file;
c. the web server comparing the uploaded file against a multitude of stored files in order to determine a set of said stored files that meet a predetermined level of similarity with said uploaded file, the predetermined level of similarity being the likeness of certain attributes of said store in the uploaded file to like attributes in stores contained in said multitude of stored files, said attributes comprising: store layout including visitor walkways, and locations, positions and sizes of shelves;
d. the web server analyzing at least one parameter in said set;
e. the web server preparing, based on said analysis, a dataset of information that is potentially relevant to said uploaded file;
f. the web server displaying said dataset to said user; and
g. the user selecting only information from said dataset that they wish to apply to the uploaded store.

In a preferred embodiment, the parameters analyzed by the web server include: in-store visitor traffic, duration visitors pause at various products, duration visitors pause at various store locations and shelves, shelf location of most popular products, and most popular location for any product. Values of these parameters are then retrieved from saved historical data taken from both physical and virtual stores. For saved historical data taken from physical stores, the values of these parameters are ascertained using a combination of heat maps retrieved from in-store infrared cameras located in, and sales information from, the physical stores. For saved historical data taken from virtual stores, the values of these parameters are ascertained using a combination of historical “stay-time” maps and sales information of these virtual stores. “Stay-time” maps are essentially detailed logs of visitor traffic within the store; how long visitors stay at a location, their path through the store, etc.

The dataset of information prepared based on these parameters comprises: a preferred shelf location for a particular product or a preferred shelf location for any product. “Preferred shelf location” in this case refers to a shelf location that would increase the chance of a visitor purchasing said product. The dataset may also comprise preferred locations for advertisements.

In another preferred embodiment, the parameter includes: store layout including visitor walkways, and locations, positions and sizes of shelves. The dataset information for this parameter is the preferred location of navigation hotspots within the store, the navigation hotspots comprising user selectable links that take said user to another store, a substore located within said store, or another location within said store.

Other objects and advantages will be more fully apparent from the following disclosure and appended claims.

### Technical Problem

Current methods of creating virtual stores require too much effort and/or expertise from the merchant.

### Solution to Problem

Providing a method for creating a virtual store on an online retail platform that automatically identifies the type of file being uploaded by the merchant from any of media files such as images and video, 3D-scan files, and computer-aided-design (CAD) files. In this way, the merchant can upload any file type and it will be automatically identified by the system. The merchant does not need to upload files in a specific order as required by some current platforms.

Providing a method for creating a virtual store on an online retail platform that registers certain parameters of the uploaded store, and finds a set of stores located in a multitude of stored files, that are close enough in those parameters to the uploaded store. The method then generates a dataset of information from the set of stores that may be relevant to the uploaded store, and displays this to the merchant. This allows the merchant to select information from this dataset that they wish to apply to the uploaded store, thus saving time and effort when creating a virtual store.

### BRIEF DESCRIPTION OF DRAWINGS

FIG. 1 shows a process flow diagram of an embodiment of this invention.

FIG. 2 shows a network architecture diagram of an embodiment of this invention.

### DETAILED DESCRIPTION OF INVENTION

It should be noted that the following detailed description is directed to a method for creating a virtual store on an online retail platform, and is not limited to any particular size or configuration but in fact a multitude of sizes and configurations within the general scope of the following description. The term “product” refers to both products and services. The terms “device” and “electronic device” are interchangeable and mean the same thing. The terms “merchant” and “user” are interchangeable and mean the same thing. The terms “store” and “storefront” are interchangeable and mean the same thing.

### LIST OF NUMBERED ELEMENTS IN FIGURES

Start of user interaction (100)
Web server offers file upload to user (102)
User uploads a file (104)
Web server identifies file type (106)
Web server stores file in appropriate servers (108)
Web server identifies parameters of uploaded store (110)
Web server retrieves parameters of stored stores (112)
Web server generates dataset of information (114)
Web server displays dataset of information to user (116)
User selects from the dataset (118)
User (or merchant) 20
Electronic device (21)
Web server (22)
Database server (23)
File server (24)
AI architecture server (25)
Deep learning server (26)

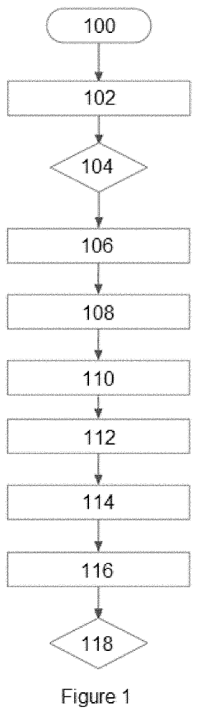

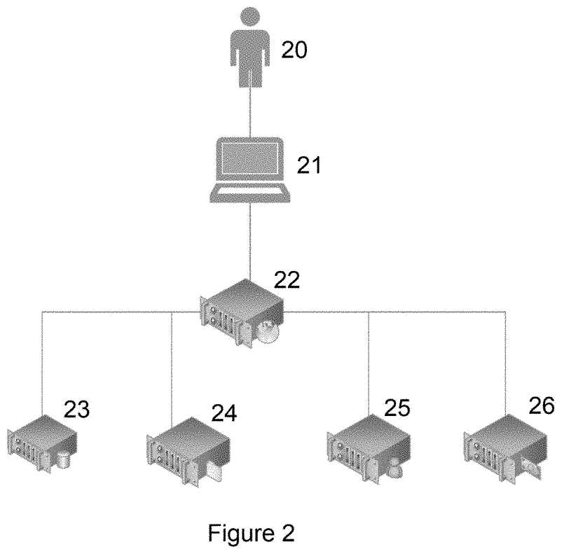

Referring to FIGS. 1 and 2, there is shown a process flow diagram of a method for a user (the merchant) to create a virtual store on an online retail platform, and a network architecture thereof. After the process starts (100), usually by initiation by a user (20) via an electronic device (21) at the user's location, a web server (22) provides (102) a means for the user (20) to upload a file. This may be a selectable link on a display of the electronic device (21). When the user (20) wants to create a virtual store, the user (20) uploads (104) a file to the web server (22). The web server identifies (106) the type of file being uploaded from any of the following types: text information file, media such as image and video files, 3D-scan file, and computer-aided-design (CAD) file. The web server (22) stores (108) text information files in a database server (23) and media, 3D-scan and CAD files in a file server (24).

If the web server (22) identifies an image or video media file being uploaded, the web server (22) compares said media file with a multitude of media files of stores stored in a deep learning server (26) via an AI architecture server (25), to find stored stores that meet a predetermined level of similarity with the uploaded store. The predetermined level of similarity here is the likeness or closeness of certain attributes of said store in the uploaded file to like attributes of stored stores. These attributes include: store layout including visitor walkways, and locations, positions and sizes of shelves. The set of stores that are found in this way are then analyzed by the web server (22). In this analysis, the web server (22) identifies (110) certain parameters that are not yet known of the uploaded store, but that may be relevant to the uploaded store and desired by the merchant to be known of the uploaded store. The webserver (22) then looks for and retrieves (112) values of these identified parameters from saved historical data of the stored stores. This saved historical data can be taken from both physical and virtual stores. For saved historical data taken from physical stores, the values of these parameters are ascertained using a combination of heat maps retrieved from in-store infrared cameras located in, and sales information from, the physical stores. For saved historical data taken from virtual stores, the values of these parameters are ascertained using a combination of historical “stay-time” maps and sales information of these virtual stores. “Stay-time” maps are essentially detailed logs of visitor traffic within the store; how long visitors stay at a location, their path through the store, etc. The web server then generates (114) a dataset of information based on the retrieved parameter values, and displays (116) them to the user. The user then selects (118) any of the displayed parameter values that they would like to be associated with the uploaded store.

If the web server (22) identifies a 3D-scan or CAD file being uploaded, the web server (22) compares said 3D-scan or CAD file with a multitude of 3D-scan or CAD files of stores stored in a deep learning server (26) via an AI architecture server (25), to find stored stores that meet a predetermined level of similarity with the uploaded store. The predetermined level of similarity here is the likeness or closeness of certain attributes of said store in the uploaded file to like attributes of stored stores. These attributes include: store layout including visitor walkways, and locations, positions and sizes of shelves. The set of stores that are found in this way are then analyzed by the web server (22). In this analysis, the web server (22) identifies (110) certain parameters that are not yet known of the uploaded store, but that may be relevant to the uploaded store and desired by the merchant to be known of the uploaded store. The webserver (22) then looks for and retrieves (112) values of these identified parameters from saved historical data of the stored stores. This saved historical data can be taken from both physical and virtual stores. For saved historical data taken from physical stores, the values of these parameters are ascertained using a combination of heat maps retrieved from in-store infrared cameras located in, and sales information from, the physical stores. For saved historical data taken from virtual stores, the values of these parameters are ascertained using a combination of historical “stay-time” maps and sales information of these virtual stores. “Stay-time” maps are essentially detailed logs of visitor traffic within the store; how long visitors stay at a location, their path through the store, etc. The web server then generates (114) a dataset of information based on the retrieved parameter values, and displays (116) them to the user. The user then selects (118) any of the displayed parameter values that they would like to be associated with the uploaded store.

The eventual dataset is determined by the parameters that are identified by the web server (22). For example, if the parameters are: in-store visitor traffic, duration visitors pause at various products, duration visitors pause at various store locations and shelves, shelf location of most popular products, and most popular location for any product, and these are ascertained using a combination of heat maps retrieved from in-store infrared cameras located in, and sales information from, physical stores, then the dataset of information prepared based on these parameters comprises: a shelf location, using a 3D x, y and z coordinate format, for a particular product that would increase the chance of a visitor purchasing said product and a preferred shelf location for any product. The dataset in this case may also comprise preferred locations for advertisements or branded content.

As a second example, if the parameter is: store layout including visitor walkways, and locations, positions and sizes of shelves, then the dataset information for this parameter is the preferred location of navigation hotspots within the store, the navigation hotspots comprising user selectable links that take said user to another store, a substore located within said store, or another location within said store.

There is an option for the user (20) to modify some of the details of the dataset as they are selecting them. The web server (22) records the selection of dataset details chosen by the user (20), along with any modifications, and applies these to the uploaded store whenever that store is displayed on the online platform.

In this way, the user (20) does not have to input a lot of data while creating a store. Some of the data the user would have had to input while creating a store could be in the dataset prepared by the web server (22).

The user (20) is given the option of choosing for the store to be displayed in either a static or a dynamic fashion. A static display comprises still images of the store being displayed in a 3D virtual environment, in which a visitor may move around. A dynamic display comprises a video of the store being displayed, and a visitor to this store being only able to pause, rewind and fast forward the video.

While several particularly preferred embodiments of the present invention have been described and illustrated, it should now be apparent to those skilled in the art that various changes and modifications can be made without departing from the scope of the invention. Accordingly, the following claims are intended to embrace such changes, modifications, and areas of application that are within the scope of this invention.

1. A computer-based method for a user (20) to create a virtual store on an online retail platform, comprising the steps of:
a. the user uploading (106) at least one file to a web server (22);
b. the web server (22) detecting (108) type of said uploaded file from any of the following types: text information file, media such as images and video, 3D-scan, and computer-aided-design (CAD) file;
c. the web server comparing the uploaded file against a multitude of stored files in order to determine a set of said stored files that meet a predetermined level of similarity with said uploaded file;
d. the web server (22) analyzing at least one parameter in said set;
e. the web server (22) preparing, based on said analysis, a dataset of information that is potentially relevant to said uploaded file;
f. the web server (22) displaying said dataset to said user; and
g. the user selecting only information from said dataset that they wish to apply to the uploaded store.

2. A computer-based method for a user (20) to create a virtual store on an online retail platform according to claim 1, wherein said at least one parameter include: in-store visitor traffic, duration visitors pause at various products, duration visitors pause at various store locations and shelves, shelf location of most popular products, and most popular location for any product.

3. A computer-based method for a user (20) to create a virtual store on an online retail platform according to claim 2, wherein said parameters are ascertained using a combination of historical heat maps retrieved from in-store infrared cameras located in, and sales information from, physical stores.

4. A computer-based method for a user (20) to create a virtual store on an online retail platform according to claim 2, wherein said parameters are ascertained using a combination of historical “stay-time” maps and sales information of virtual stores.

5. A computer-based method for a user (20) to create a virtual store on an online retail platform according to claim 2, wherein said dataset of information include: a preferred shelf location for a particular product.

6. A computer-based method for a user (20) to create a virtual store on an online retail platform according to claim 2, wherein said dataset of information include: a preferred shelf location for any product

7. A computer-based method for a user (20) to create a virtual store on an online retail platform according to claim 2, wherein the dataset further comprises preferred locations for advertisements.

8. A computer-based method for a user (20) to create a virtual store on an online retail platform according to claim 1, wherein said at least one parameter includes: store layout including visitor walkways and product shelves.

9. A computer-based method for a user (20) to create a virtual store on an online retail platform according to claim 8, wherein said dataset information for said parameter is the preferred location of navigation hotspots within said store, said navigation hotspots comprising user selectable links that take said user to another store, a substore located within said store, or another location within said store.

10. A computer-based method for a user (20) to create a virtual store on an online retail platform according to claim 1 wherein the said predetermined level of similarity comprises a likeness of certain attributes of said store in the uploaded file to like attributes in stores contained in said multitude of stored files, said attributes comprising: store layout including visitor walkways, and locations, positions and sizes of shelves.
